(19) United States
(12) Patent Application Publication
(10) Pub. No.: US 2024/0196705 A1
(43) Pub. Date: Jun. 13, 2024

(54) DISPLAY DEVICE AND METHOD FOR MANUFACTURING THE SAME

(71) Applicant: Samsung Display Co., LTD., Yongin-si (KR)

(72) Inventors: HYUNKYUNG YUN, Yongin-si (KR); EUN-KYUNG YEON, Yongin-si (KR); JOOHYEON LEE, Yongin-si (KR); HOIKWAN LEE, Yongin-si (KR); HAYOUNG CHOI, Yongin-si (KR)

(21) Appl. No.: 18/524,958

(22) Filed: Nov. 30, 2023

(30) Foreign Application Priority Data
Dec. 7, 2022 (KR) 10-2022-0169577

(51) Int. Cl. H10K 59/80; H10K 59/12; H10K 59/38; H10K 77/10

(52) U.S. Cl. CPC H10K 59/873; H10K 59/1201; H10K 59/38; H10K 77/111; H10K 2102/311

(57) ABSTRACT

A display device includes a display module and a protection member disposed on the display module. The protection member includes a first protection layer and a second protection layer disposed on the first protection layer. The first protection layer has a storage modulus in a range of about 0.005 MPa to about 0.2 MPa at a room temperature. The second protection layer has a first thickness in a range of about 300 μm to about 1 mm, and has a Young's modulus in a range of about 1 GPa to about 8 GPa at the room temperature.

This application claims priority to Korean Patent Application No. 10-2022-0169577, filed on Dec. 7, 2022, and all the benefits accruing therefrom under 35 U.S.C. § 119, the content of which in its entirety is herein incorporated by reference.

### BACKGROUND

### 1. Field

The invention relates to a display device not including a polarizing plate, and a method for manufacturing the display device.

### 2. Description of the Related Art

A display device displays various images on a display screen to provide information to a user. In general, the display device displays information in an allotted screen. Recently, flexible display devices including a flexible display panel which is foldable are being developed. A flexible display device may be folded, rolled, or bent, unlike a rigid display device. A flexible display device, the shape of which may be variously changed, may be portable regardless of the original screen size thereof, so that user convenience may be improved.

A protection member may be disposed in the uppermost portion of a display device. A protection member included in a foldable flexible display device may have impact resistance characteristics.

### SUMMARY

The disclosure provides a display device with improved impact resistance.

The disclosure also provides a method for manufacturing a display device with improved manufacturing efficiency.

An embodiment of the invention provides a display device including a display module; and a protection member disposed on the display module, where the protection member includes a first protection layer having a storage modulus in a range of about 0.005 megapascal (MPa) to about 0.2 MPa at a room temperature, and a second protection layer disposed on the first protection layer, having a first thickness in a range of about 300 micrometers (μm) to about 1 millimeter (mm), and having a Young's modulus in a range of about 1 gigapascal (GPa) to about 8 GPa at the room temperature.

In an embodiment, the protection member may be directly disposed on the display module.

In an embodiment, the protection member may not include a glass substrate.

In an embodiment, the first protection layer may have a second thickness in a range of about 100 μm to about 1 mm.

In an embodiment, the first thickness of the second protection layer may be greater than or equal to a second thickness of the first protection layer.

In an embodiment, the protection member may have a third thickness in a range of about 400 μm to about 2 mm.

In an embodiment, the second protection layer may be directly disposed on the first protection layer.

In an embodiment, each of the first protection layer and the second protection layer may include at least one of an epoxy-based resin, a urethane-based resin, an acrylic resin, or a silicon-based resin.

In an embodiment, the second protection layer may further include at least one of silsesquioxane nano particles or silica nano particles.

In an embodiment, no polarizing plate is included.

In an embodiment, the display module may include a display panel and an optical layer disposed on the display panel, wherein the optical layer may include a pigment or a dye.

In an embodiment, the optical layer may include a pattern portion in which a pattern opening is defined, and first to third filters each of which includes the pigment or the dye, and is disposed by filling the pattern opening.

In an embodiment of the invention, a method for manufacturing a display device includes preparing a display module including a display panel and an optical layer disposed on the display panel, where the optical layer includes a pigment or a dye, and forming a protection member on the display module at a temperature in a range of a room temperature to about 80° C., where the forming the protection member includes providing a first resin composition on the display module, forming a preliminary first protection layer by curing the first resin composition, providing a second resin composition on the preliminary first protection layer, and forming a first protection layer and a second protection layer of the protection member by curing the preliminary first protection layer and the second resin composition.

In an embodiment, the first resin composition may be directly provided on the display module.

In an embodiment, the second resin composition may be directly provided on the preliminary first protection layer.

In an embodiment, the preliminary first protection layer and the second resin composition may be cured during a same process.

In an embodiment, each of the first resin composition and the second resin composition may be provided by an inkjet printing method, a dispensing method, or a slot-die coating method.

In an embodiment, the first resin composition may include a solvent in an amount in a range of about 0 wt % to about 10 wt % based on a total weight of the first resin composition.

In an embodiment, the second resin composition may include a solvent in an amount in a range of about 0 wt % to about 10 wt % based on a total weight of the second resin composition.

In an embodiment, each of the first resin composition and the second resin composition may include at least one of an epoxy-based resin, a urethane-based resin, an acrylic resin, or a silicon-based resin.

In an embodiment, the second resin composition may further include at least one of silsesquioxane nano particles or silica nano particles.

In an embodiment, the second protection layer may have a Young's modulus in a range of about 1 GPa to about 8 Gpa at the room temperature, and the second protection layer may have a first thickness in a range of about 300 μm to about 1 mm.

In an embodiment, the first protection layer may have a storage modulus in a range of about 0.005 MPa to about 0.2 MPa at the room temperature, and the first protection layer may have a second thickness in a range of about 100 μm to about 1 mm.

### BRIEF DESCRIPTION OF THE DRAWINGS

The above and other features of the invention will become more apparent by describing in further detail embodiments thereof with reference to the accompanying drawings, in which:

FIG. 1 is a perspective view showing a display device of an embodiment of the invention;

FIG. 2A is a perspective view showing a display device of an embodiment of the invention;

FIG. 2B is a perspective view showing a display device of an embodiment of the invention;

FIG. 3 is a cross-sectional view showing a display device of an embodiment of the invention;

FIG. 4 is a cross-sectional view showing a portion of a display device according to an embodiment of the invention;

FIG. 5 is a cross-sectional view showing a portion of a display device according to an embodiment of the invention;

FIG. 6 shows the measurement of heights at which bright spots occur in Comparative Examples and Experimental Examples;

FIG. 7 shows the measurement of heights at which bright spots occur in Comparative Examples and Experimental Examples;

FIG. 8 shows the measurement of heights at which bright spots occur in Comparative Examples and Experimental Examples;

FIG. 9A is a flowchart showing a method for manufacturing a display device of an embodiment of the invention;

FIG. 9B is a flowchart showing a method for manufacturing a display device of an embodiment of the invention; and

FIG. 10 to FIG. 14 are cross-sectional views schematically showing processes of a method for manufacturing a display device of an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the specification, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. “At least one of A, B or C” means “least one selected from A, B and C.”

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the invention. The terms of a singular form may include plural forms unless the context clearly indicates otherwise.

In addition, terms such as “below,” “lower,” “above,” “upper,” and the like are used to describe the relationship of the elements shown in the drawings. The terms are used as a relative concept and are described with reference to the direction indicated in the drawings.

It should be understood that the term “comprise,” “include,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, with reference to the accompanying drawings, embodiments of a display device will be described in detail.

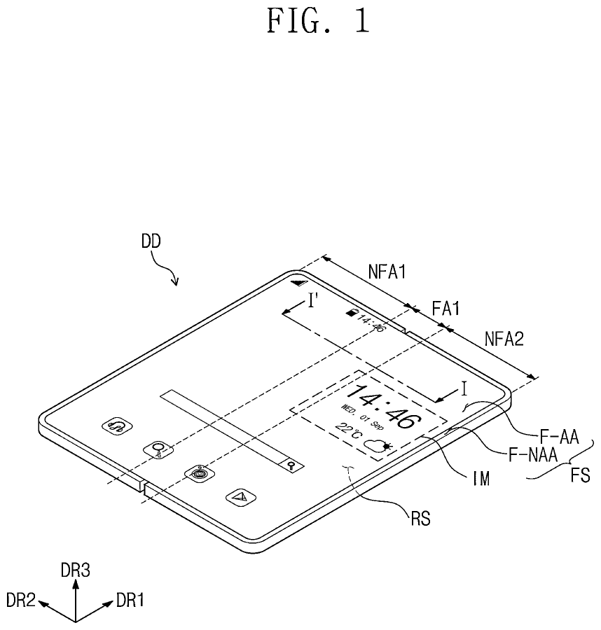

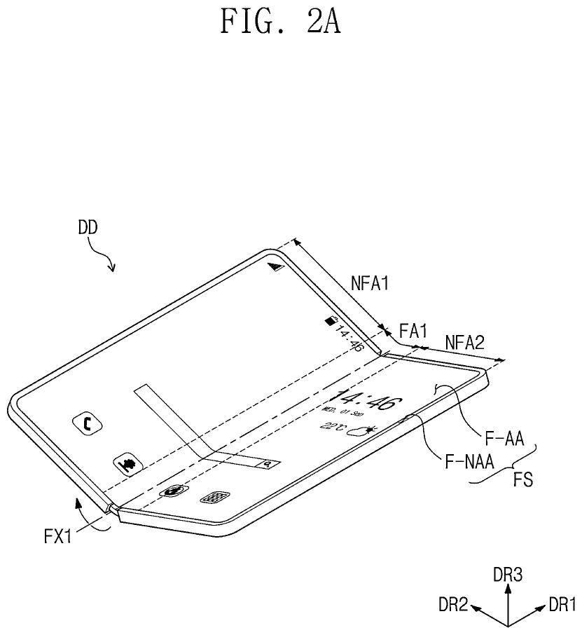

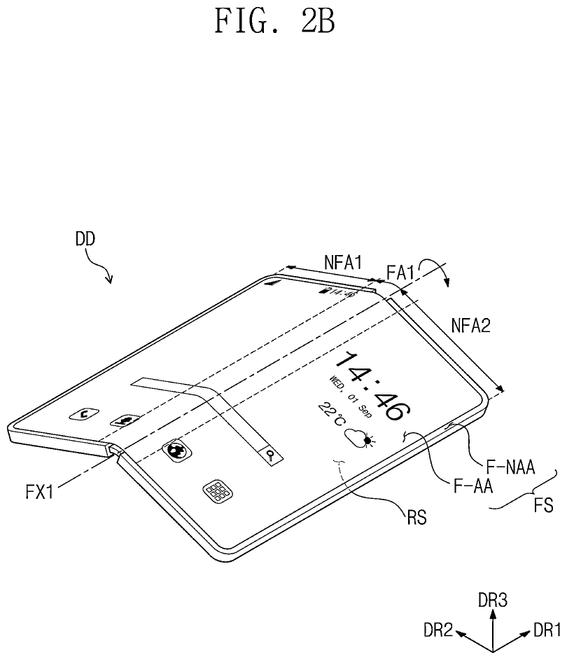

FIG. 1 is a perspective view showing a display device according to an embodiment of the invention. FIG. 2A is a perspective view showing an inner-folding process of the display device illustrated in FIG. 1. FIG. 2B is a perspective view showing an outer-folding process of the display device illustrated in FIG. 1.

A display device DD according to an embodiment may be a device activated according to an electrical signal. The display device DD may be a flexible device. In an embodiment, for example, the display device DD may be a portable electronic apparatus, a tablet computer, a car navigation system unit, a game console, a personal computer, a laptop computer, or a wearable device, but is not limited thereto. In FIG. 1, an embodiment where the display device DD is a portable electronic apparatus is illustrated as an example.

The display device DD may display an image IM through a display surface FS. The display surface FS may include an active region F-AA and a peripheral region F-NAA. The active region F-AA may be a region activated according to an electrical signal. The display device DD may display the image IM through the active region F-AA. In addition, various forms or types of external inputs may be sensed in the active region F-AA. The peripheral region F-NAA may be adjacent to the active region F-AA. The peripheral region F-NAA may surround the active region F-AA. Accordingly, the shape of the active region F-AA may substantially be defined by the peripheral region F-NAA. However, this is only an example, and alternatively, the peripheral region F-NAA may be disposed adjacent to only one side of the active region F-AA, or may be omitted. The display surface FS may include or be on a plane defined by a first direction axis DR1 and a second direction axis DR2.

A rear surface RS of the display device DD may be a surface facing the display surface FS. In an embodiment, for example, the rear surface RS may be an external surface of the display device DD, and a video or an image may not be displayed thereon. On the contrary, the rear surface RS may function as a second display surface on which a video or an image is displayed.

In the specification, the first direction axis DR1 and the second direction axis DR2 are perpendicular to each other, and a third direction axis DR3 may be a normal direction with respect to a plane defined by the first direction axis DR1 and the second direction axis DR2. A thickness direction of the display device DD may be a direction parallel to the third direction axis DR3. On the basis of the third direction axis DR3, an upper surface (or upper side) and a lower surface (or lower side) may be defined. The upper surface (or upper side) refers to a surface (or direction) adjacent to the display surface FS, and the lower surface (or lower side) refers to a surface (or direction) adjacent to the rear surface RS. A cross-section refers to a surface parallel to the thickness direction DR3, and a plane refers to a surface perpendicular to the thickness direction DR3. The plane refers to a plane defined by the first direction axis DR1 and the second direction axis DR2.

Directions indicated by the first to third direction axes DR1, DR2, and DR3 described in the specification are a relative concept, and may be converted into different directions. In addition, the directions indicated by the first to third direction axes DR1, DR2, and DR3 may be referred to as first to third directions, and may be denoted by the same reference numerals.

The display device DD may include a folding region FA1 and non-folding regions NFA1 and NFA2. The display device DD may include a plurality of non-folding regions NFA1 and NFA2. The display device DD may include a first non-folding region NFA1 and a second non-folding region NFA2 spaced apart from each other with the folding region FA1 interposed therebetween.

FIG. 1 to FIG. 2B illustrate an embodiment of the display device DD including a single folding region FAT, but this is only an example, and the display device DD may have a plurality of folding regions. In addition, the display device DD may be folded on the basis of a plurality of folding axes such that portions of the display surface FS may be folded to face each other, and the number of folding axes and the number of non-folding regions in accordance therewith are not limited to any one embodiment.

Referring to FIG. 2A and FIG. 2B, the display device DD may be folded on the basis of a first folding axis FX1. The first folding axis FX1 illustrated in FIG. 2A and FIG. 2B is an imaginary axis extending in the first direction DR1, and the first folding axis FX1 may be parallel to a long side direction of the display device DD. However, this is only an example, and an extension direction of the first folding axis FX1 is not limited to the first direction DR1.

The first folding axis FX1 may extend along the first direction axis DR1 on the display surface FS, or may extend along the first direction axis DR1 on a lower side of the rear surface RS. Referring to FIG. 2A, the first non-folding region NFA1 and the second non-folding region NFA2 may face each other, and the display device DD may be inner-folded such that the display surface FS is not exposed to the outside. Referring to FIG. 2B, the display device DD may be folded on the basis of the first folding axis FX1 and transformed into an outer-folded state in which, on the rear surface RS, one region overlapping the first non-folding region NFA1 and the other region overlapping the second non-folding region NFA2 face each other.

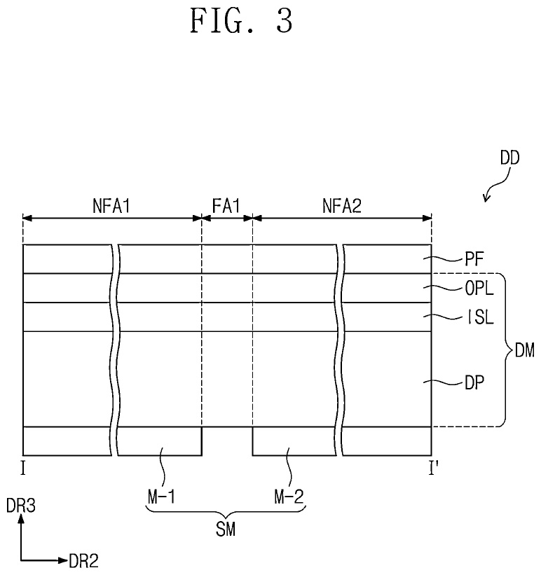

FIG. 3 is a cross-sectional view showing a portion corresponding to line I-I′ of FIG. 1. FIG. 3 may be a schematic cross-sectional view showing the display device DD according to an embodiment of the invention.

Referring to FIG. 3, an embodiment of the display device DD may include a display module DM, and a protection member PF disposed on the display module DM. In addition, the display device DD may further include a support member SM disposed on a lower side of the display module DM.

The protection member PF may be a component which protects the display module DM and the like disposed on a lower side of the protection member PF. The protection member PF may be optically transparent. In an embodiment, for example, the protection member PF may have a transmittance of about 85% or higher, e.g., about 90% or higher, in a visible light region. An image generated in the display module DM may transmit the protection member PF and be provided to a user.

In an embodiment, the protection member PF may be directly disposed on the display module DM. An adhesive member may not be disposed between the protection member PF and the display module DM. The protection member PF may not include a glass substrate. In addition, a glass substrate may not be included between the display module DM and the protection member PF. The protection member PF may be a component disposed in or defining the uppermost portion of the display device DD.

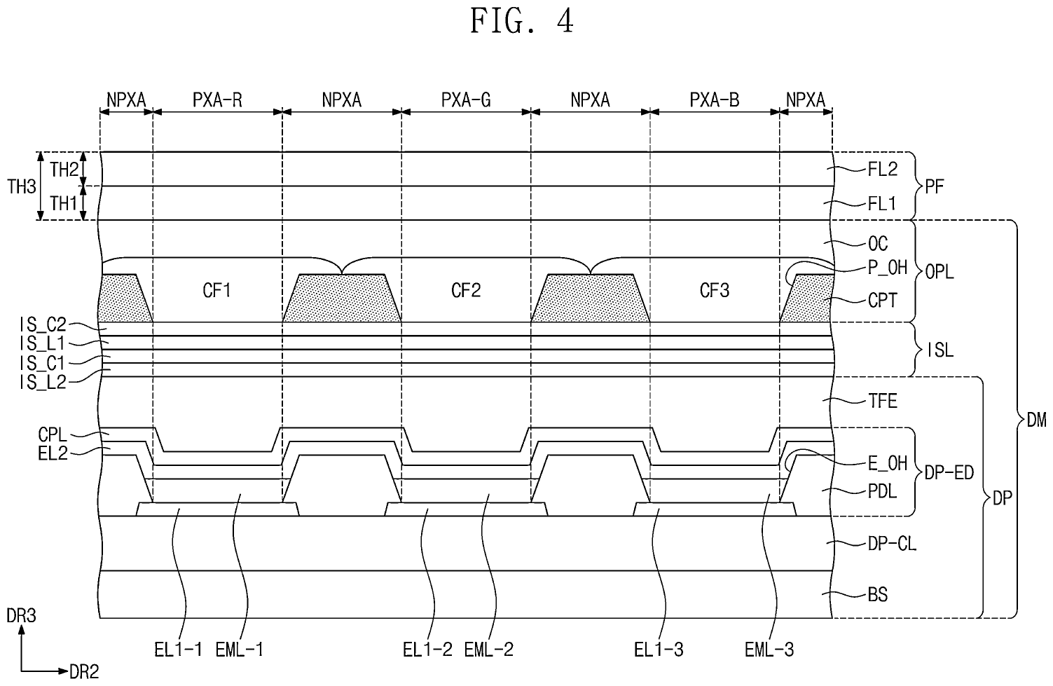

In a method for manufacturing a display device of an embodiment to be described later, the protection member PF may be formed by applying and curing a composition, and a glass substrate is not suitable to be formed by applying and curing a composition. Accordingly, the protection member PF does not include a glass substrate. The protection member PF may include a first protection layer FL1 (see FIG. 4) and a second protection layer FL2 (see FIG. 4) which satisfy a predetermined modulus (e.g., a Young's modulus and a storage modulus) range and a predetermined thickness range. Accordingly, the display device DD including the protection member PF may exhibit high impact resistance. The protection member PF will be described in greater detail later.

In the specification, when one element is directly disposed on another element, it mean that there is no third element disposed between the one element and the another element. That is, when one element is “directly disposed” on another element, it means that the one element and the another element are in “direct contact” with each other.

The display module DM may be a component configured to generate an image and sense an input applied from the outside. The display module DM may include a display panel DP and an optical layer OPL disposed on the display panel DP. In addition, the display module DM may further include an input sensing layer ISL disposed between the display panel DP and the optical layer OPL.

The display panel DP may be a component which substantially generates an image. The display panel DP may be a light emitting-type display panel, and for example, the display panel DP may be an organic light emitting display panel, an inorganic light emitting display panel, a quantum-dot display panel, a micro-light emitting diode (LED) display panel, or a nano-LED display panel. The display panel DP may also be referred to as a display layer.

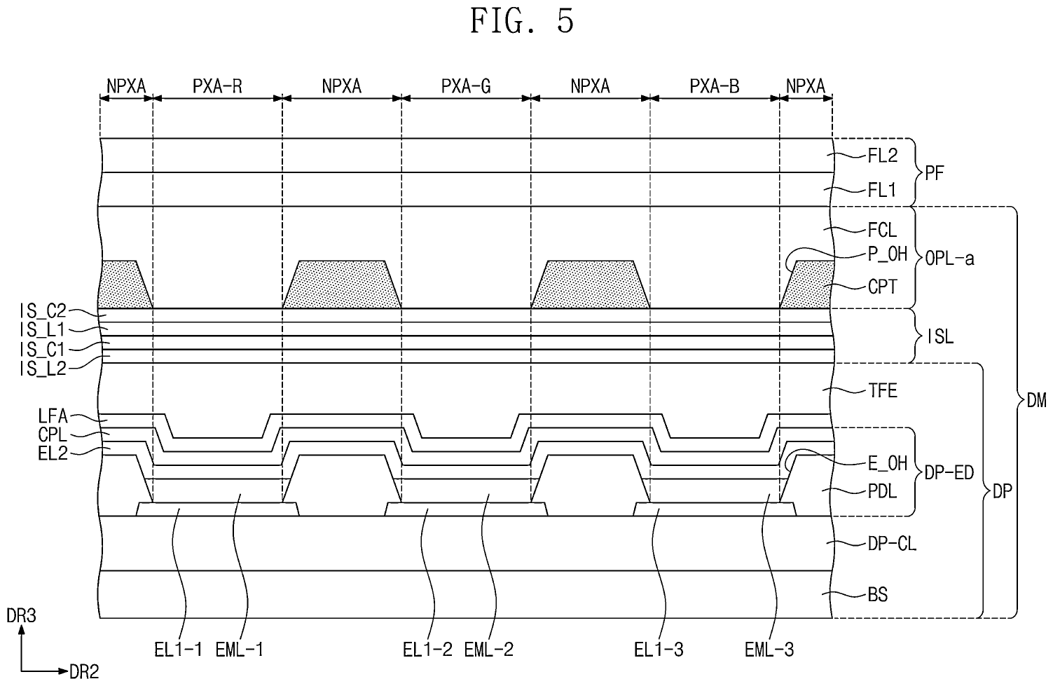

The input sensing layer ISL may be disposed on the display panel DP. In an embodiment, for example, the input sensing layer ISL may be directly disposed on an encapsulation layer TFE (see FIGS. 4 and 5) of the display panel DP. The input sensing layer ISL may sense an external input, change the external input into a predetermined input signal, and provide the input signal to the display panel DP. In an embodiment, for example, in the display device DD of an embodiment, the input sensing layer ISL may be a touch sensing layer configured to sense a touch. The input sensing layer ISL may recognize a direct touch of a user, an indirect touch of a user, a direct touch of an object, an indirect touch of an object, or the like.

The input sensing layer ISL may sense at least of the position of a touch, which is applied externally, or the intensity (pressure) of the touch. The input sensing layer ISL may have various configurations, or may include or be formed of various materials, and is not limited to any one embodiment. In an embodiment, for example, the input sensing layer ISL may sense an external input in a capacitive manner. The display panel DP may receive an input signal from the input sensing layer ISL, and may generate an image corresponding to the input signal.

The optical layer OPL may be disposed on the input sensing layer ISL. The optical layer OPL may include a pigment or a dye. The optical layer OPL may be a layer which selectively transmits light emitted from the display panel DP. The optical layer OPL may be a layer which reduces the reflectance of external light incident from the outside. The optical layer OPL does not include a polarizing plate. The display device DD of an embodiment does not include the polarizing plate. In an embodiment, the display device DD, which does not include the polarizing plate, and which includes the protection member PF, may exhibit improved impact resistance.

The support member SM may include a first support portion M-1 and a second support portion M-2 spaced apart from each other in the second direction DR2. The first support portion M-1 may be disposed to correspond to the first non-folding region NFA1, and the second support portion M-2 may be disposed to correspond to the second non-folding region NFA2. The first support portion M-1 and the second support portion M-2 may not overlap the folding region FAT. However, the embodiment of the invention is not limited thereto, and a portion of each of the first support portion M-1 and the second support portion M-2 may overlap the folding region FA1. The support member SM may include a metal material, a polymer material, a non-metal material, plastic, glass fiber reinforced plastic, or glass.

In an embodiment, although not illustrated, the display device DD may further include a module protection layer (not shown) disposed between the display module DM and the support module SM. In addition, the display device DD may further include a cushion layer (not shown) disposed on a lower side of the support member SM. However, this is only an example, and the configuration disposed on a lower side of the display module DM is not limited thereto. The configuration disposed on the lower side of the display module DM may further include an additional support plate, an adhesive layer, and the like, depending on the size, shape, or operation properties of the display device DD.

The module protection layer (not shown) may be a layer disposed on the lower side of the display module DM to protect the rear surface of the display module DM. The module protection layer (not shown) may overlap the entire display module DM. The module protection layer (not shown) may include a polymer material. In an embodiment, for example, the module protection layer (not shown) may be a polyimide film or a polyethylene terephthalate film.

The cushion layer (not shown) may protect the support member SM from external impact and force. In an embodiment, for example, the cushion layer (not shown) may include an elastomer such as sponge, foam, or a urethane resin, and the like. In addition, the cushion layer (not shown) may include or be formed by using at least one of an acrylic polymer, a urethane-based polymer, a silicon-based polymer, or an imide-based polymer.

FIG. 4 is a cross-sectional view showing the display module DM and the protection member PF of FIG. 3. Particularly, FIG. 4 is a cross-sectional view showing the display panel DP, the input sensing layer ISL, the optical layer OPL, and the protection member PF in greater detail.

Referring to FIG. 4, in an embodiment, the display panel DP may include a base layer BS, a circuit layer DP-CL disposed on the base layer BS, a display element layer DP-ED disposed on the circuit layer DP-CL, and the encapsulation layer TFE disposed on the display element layer DP-ED.

The base layer BS may be a member which provides a base surface on which the display element layer DP-ED is disposed. The base layer BS may be a glass substrate, a metal substrate, a polymer substrate, or the like. However, the embodiment of the invention is not limited thereto, and the base layer BS may be an inorganic layer, an organic layer, or a composite material layer.

The base layer BS may include or defined by a single layer or multiple layers. In an embodiment, for example, the base layer BS may include a first synthetic resin layer, a multi-layered or single-layered inorganic layer, and a second synthetic resin layer disposed on an upper side of the multi-layered or single-layered inorganic layer. Each of the first synthetic resin layer and the second synthetic resin layer may include a polyimide-based resin. In addition, each of the first synthetic resin layer and the second synthetic resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In the specification, a “˜˜-based” resin means that a functional group of “˜˜” is included.

The circuit layer DP-CL may include an insulation layer, a semiconductor pattern, a conductive pattern, a signal line, and the like. The circuit layer DP-CL may include a plurality of transistors (not shown). Each of the transistors (not shown) may include a control electrode, an input electrode, and an output electrode. In an embodiment, for example, the circuit layer DP-CL may include a switching transistor and a driving transistor for driving components of the display element layer DP-ED (e.g., a first electrode, a light emitting layer, and a second electrode).

The display element layer DP-ED may include a pixel definition film PDL in which a pixel opening E_OH is defined, first electrodes EL1-1, EL1-2, and EL1-3 exposed by the pixel opening E_OH, light emitting layers EML-1, EML-2, and EML-3 disposed on the first electrodes EL1-1, EL1-2, and EL1-3, and a second electrode EL2 disposed on the light emitting layers EML-1, EML-2, and EML-3.

The display panel DP may be divided into light emitting regions PXA-R, PXA-G, and PXA-B and a non-light emitting region NPXA. The light emitting regions PXA-R, PXA-G, and PXA-B may be spaced apart from each other on a plane. The light emitting regions PXA-R, PXA-G, and PXA-B may be regions from which light generated in the display element layer DP-ED is emitted. The light emitting regions PXA-R, PXA-G, and PXA-B may include a red light emitting region PXA-R, a green light emitting region PXA-G, and a blue light emitting region PXA-B distinguished from each other. Each of the light emitting regions PXA-R, PXA-G, and PXA-B may be a region distinguished or defined by the pixel definition film PDL. The non-light emitting regions NPXA are regions between the light emitting regions PXA-R, PXA-G, and PXA-B, and may be regions corresponding to the pixel defining film PDL.

The pixel definition film PDL may have a property of absorbing light. The pixel definition film PDL may include a black coloring agent. The black coloring agent may include a black dye, or a black pigment. The black coloring agent may include carbon black, a metal such as chromium, or an oxide thereof. The pixel definition film PDL may cover a portion of the first electrodes EL1-1, EL1-2, and EL1-3. In the specification, the overlapping of one element and another element is not limited to the one component and the another element having a same area and a same shape as each other, and includes the one component and the another component having different areas and/or different shapes from each other.

The first electrodes EL1-1, EL1-2, and EL1-3 may be anodes or cathodes. In addition, the first electrodes EL1-1, EL1-2, and EL1-3 may be pixel electrodes. The first electrodes EL1-1, EL1-2, and EL1-3 may be transmissive electrodes, transflective electrodes, or reflective electrodes. In an embodiment where the first electrodes EL1-1, EL1-2, and EL1-3 are transmissive electrodes, the first electrodes EL1-1, EL1-2, and EL1-3 may include a transparent metal oxide, for example, indium tin oxide (ITO), indium zinc oxide (IZO), zinc oxide (ZnO), indium tin zinc oxide (ITZO), or the like. In an embodiment where the first electrodes EL1-1, EL1-2, and EL1-3 are transflective electrodes or reflective electrodes, the first electrodes EL1-1, EL1-2, and EL1-3 may include Ag, Mg, Cu, Al, Pt, Pd, Au, Ni, Nd, Ir, Cr, Li, Ca, LiF/Ca, LiF/Al, Mo, Ti, W, or a compound or mixture thereof (e.g., a mixture of Ag and Mg). Alternatively, the first electrodes EL1-1, EL1-2, and EL1-3 may have a multi-layered structure including a reflective film or transflective film formed of the above exemplified materials, and a transparent conductive film formed of indium tin oxide (ITO), indium zinc oxide (IZO), zinc oxide (ZnO), indium tin zinc oxide (ITZO), or the like. In an embodiment, for example, the first electrodes EL1-1, EL1-2, and EL1-3 may have a three-layered structure of ITO/Ag/ITO, but are not limited thereto.

The display element layer DP-ED may include the plurality of light emitting layers EML-1, EML-2, and EML-3. Each of the light emitting layers EML-1, EML-2, and EML-3 may be patterned and provided inside the pixel opening E_OH defined on the pixel definition film PDL. The light emitting layers EML-1, EML-2, and EML-3 may overlap the light emitting regions PXA-R, PXA-G, and PXA-B. The display element layer DP-ED may include a first light emitting layer EML-1 corresponding to a first light emitting region PXA-R, a second light emitting layer EML-2 corresponding to a second light emitting region PXA-G, and a third light emitting layer EML-3 corresponding to a third light emitting region PXA-B. The light emitting layers EML-1, EML-2, and EML-3 may respectively emit light of different wavelength regions. In an embodiment, for example, the first light emitting layer EML-1 may emit red light, the second light emitting layer EML-2 may emit green light, and the third light emitting layer EML-3 may emit blue light.

Each of the light emitting layers EML-1, EML-2, and EML-3 may include an organic light emitting material or an inorganic light emitting material. In an embodiment, for example, each of the light emitting layers EML-1, EML-2, and EML-3 may include a fluorescent or phosphorescent material. Each of the light emitting layers EML-1, EML-2, and EML-3 may include an anthracene derivative, a pyrene derivative, a fluoranthene derivative, a chrysene derivative, a dihydrobenz anthracene derivative, or a triphenylene derivative. In addition, the light emitting layers EML-1, EML-2, and EML-3 may include an organometallic complex as a light emitting material. The light emitting layers EML-1, EML-2, and EML-3 may include a quantum dot as a light emitting material.

Each of the light emitting layers EML-1, EML-2, and EML-3 may be provided as or defined by a single layer or multiple layers. In an embodiment, for example, when the first light emitting layers EML-1 is provided as multiple layers, a charge generation layer (not shown) may be disposed between a plurality of first light emitting layers EML-1. However, this is only an example, and the embodiment of the invention is not limited thereto.

The second electrode EL2 may be a common electrode. The second electrode EL2 may be a cathode or an anode, but the embodiment of the invention is not limited thereto. In an embodiment, for example, where the first electrodes EL1-1, EL1-2, and EL1-3 are anodes, the second electrode EL2 may be a cathode. In an embodiment, for example, where the first electrodes EL1-1, EL1-2, and EL1-3 are cathodes, the second electrode EL2 may be an anode.

The second electrode EL2 may be a transmissive electrode, a transflective electrode, or a reflective electrode. In an embodiment where the second electrode EL2 is a transmissive electrode, the second electrode EL2 may include or be formed of a transparent metal oxide, for example, indium tin oxide (ITO), indium zinc oxide (IZO), zinc oxide (ZnO), indium tin zinc oxide (ITZO), or the like.

Although not illustrated, a hole transport region (not shown) may be disposed between the first electrodes EL1-1, EL1-2, and EL1-3 and the light emitting layers EML-1, EML-2, and EML-3, and the hole transport region may include at least one of a hole transport layer, a hole injection layer, or an electron blocking layer. In addition, an electron transport region (not shown) may be disposed between the light emitting layers EML-1, EML-2, and EML-3 and the second electrode EL2, and the electron transport region may include at least one of an electron transport layer, an electron injection layer, or a hole blocking layer. Each of the hole transport region and the electron transport region may be provided as a common layer, or may be patterned and provided inside the pixel opening E_OH.

The display element layer DP-ED may further include a capping layer CPL disposed on the second electrode EL2. The capping layer CPL may include a single layer or multiple layers. The capping layer CPL may include an organic substance or an inorganic substance. In an embodiment, the capping layer CPL may be an organic layer, or an inorganic layer. In an embodiment, for example, when the capping layer CPL includes an inorganic substance, the inorganic substance may include an alkaline metal compound such as LiF, an alkaline earth metal compound such as MgF₂, silicon oxynitride, silicon nitride, silicon oxide, or the like. In an embodiment, for example, where the capping layer CPL includes an organic substance, the organic substance may include α-NPD, N,N′-di(naphthalene-1-yl)-N,N′-diphenyl-benzidine (NPB), N,N′-bis(3-methylphenyl)-N,N′-diphenyl-[1,1′-biphenyl]-4,4′-diamine (TPD), 4,4′,4″-[tris(3-methylphenyl)phenylamino] triphenylamine (m-MTDATA), Alq₃, CuPc, N4,N4,N4′,N4′-tetra (biphenyl-4-yl) biphenyl-4,4′-diamine (TPD15), 4,4′,4″-Tris (carbazol-9-yl) triphenylamine (TCTA), or the like, or may include an epoxy resin, or an acrylate such as a methacrylate.

The refractive index of the capping layer CPL may be about 1.6 or greater. In an embodiment, for example, for light in a wavelength region of about 550 nanometers (nm) to about 660 nm, the refractive index of the capping layer CPL may be about 1.6 or greater. The capping layer CPL may improve light efficiency by the principle of constructive interference.

The encapsulation layer TFE may seal the display element layer DP-ED. The encapsulation layer TFE may include at least one inorganic film (hereinafter, an encapsulation inorganic film). In addition, the encapsulation layer TFE may include at least one organic film (hereinafter, an encapsulation organic film) and at least one encapsulation inorganic film. The encapsulation inorganic film may protect the display element layer DP-ED from moisture/oxygen, and the encapsulation organic film may protect the display element layer DP-ED from foreign materials such as dust particles. The encapsulation inorganic film may include silicon nitride, silicon oxynitride, silicon oxide, titanium oxide, aluminum oxide, or the like, but is not particularly limited thereto. The encapsulation organic film may include an acrylic compound, an epoxy-based compound, or the like. The encapsulation organic film may include a photopolymerizable organic material, but is not particularly limited thereto.

The input sensing layer ISL may include a base insulation layer IS_L2, a first conductive layer IS_C1 disposed on the base insulation layer IS_L2, a second conductive layer IS_C2 disposed on the first conductive layer IS_C1, and a touch insulation layer IS_L1 disposed between the first conductive layer IS_C1 and the second conductive layer IS_C2. The base insulation layer IS_L2 may include or be defined by a single layer or multiple layers. The base insulation layer IS_L2 may include an organic substance or an inorganic substance. The base insulation layer IS_L2 may include at least of silicon nitride, silicon oxynitride, or silicon oxide. Alternatively, the base insulation layer IS_L2 may include an epoxy resin, an acrylic resin, or an imide-based resin.

The touch insulation layer IS_L1 may include an organic substance or an inorganic substance. In an embodiment, for example, the touch insulation layer IS_L1 may include at least one of an epoxy-based resin, a urethane-based resin, a cellulose-based resin, a siloxane-based resin, a polyimide-based resin, a polyamide-based resin, or a perylene-based resin. Alternatively, the touch insulation layer IS_L1 may include at least one of aluminum oxide, titanium oxide, silicon oxide, silicon nitride, silicon oxynitride, zirconium oxide, or hafnium oxide.

Each of the first conductive layer IS_C1 and the second conductive layer IS_C2 may include a single layer or multiple layers. Each of the first conductive layer IS_C1 and the second conductive layer IS_C2 may include or be defined by a single layer of a metal layer or of a transparent conductive layer. The metal layer may include molybdenum (Mo), silver (Ag), titanium (Ti), copper (Cu), aluminum (Al), or an alloy thereof. The transparent conductive layer may include a transparent conductive oxide such as indium tin oxide (ITO), indium zinc oxide (IZO), indium tin zinc oxide (ITZO), or the like. In addition, the transparent conductive layer may include a conductive polymer such as PEDOT, a metal nanowire, graphene, or the like.

Alternatively, each of the first conductive layer IS_C1 and the second conductive layer IS_C2 may include at least one metal layer or at least one of transparent conductive layer. In an embodiment, for example, each of the first conductive layer IS_C1 and the second conductive layer IS_C2 may have a three-layered structure of ITO/Ag/ITO.

The optical layer OPL may include a pattern portion CPT and first to third filters CF1, CF2, and CF3. The pattern portion CPT may have a pattern opening P_OH defined thereon. The first to third filters CF1, CF2, and CF3 may be disposed by filling the pattern opening P_OH. In addition, the optical layer OPL may include an overcoat layer OC disposed on the pattern portion CPT and the first to third filters CF1, CF2, and CF3.

A material constituting the pattern portion CPT is not particularly limited as long as it is a material absorbing light. The pattern portion CPT has a black color, and the pattern portion CPT may include a black coloring agent. The black coloring agent may include a black dye or a black pigment. The black coloring agent may include carbon black, a metal such as chromium, or an oxide thereof.

The first to third filters CF1, CF2, and CF3 may be disposed to correspond to the light emitting layers EML-1, EML-2, and EML-3. The optical layer OPL may include a first filter CF1 corresponding to the first light emitting layer EML-1, a second filter CF2 corresponding to the second light emitting layer EML-2, and a third filter CF3 corresponding to the third light emitting layer EML-3. Each of the first to third filters CF1, CF2, and CF3 may include a pigment or a dye. In an embodiment, for example, the first filter CF may be a red filter, the second filter CF2 may be a green filter, and the third filter CF3 may be a blue filter. Accordingly, the optical layer OPL including the first to third filters CF1, CF2, and CF3 may improve the display quality of the display device DD.

The overcoat layer OC may cover the pattern portion CPT and the first to third filters CF1, CF2, and CF3. The overcoat layer OC may include an organic substance. The overcoat layer OC may be a planarization layer.

In an embodiment, the protection member PF may include the first protection layer FL1 and the second protection layer FL2 disposed on the first protection layer FL1. The first protection layer FL1 may be directly disposed on the display module DM. The second protection layer FL2 may be directly disposed on the first protection layer FL1. In the method for manufacturing a display device of an embodiment to be described later, the second protection layer FL2 and the first protection layer FL1 are formed by applying and curing a composition, and a composition for the formation of the second protection layer FL2 may be directly applied on a preliminary first protection layer P-FL1 (see FIG. 12) for the formation of the first protection layer FL1.

Each of the first protection layer FL1 and second protection layer FL2 may include at least one of an epoxy-based resin, a urethane-based resin, an acrylic resin, or a silicon-based resin. In an embodiment, for example, each of the first and second protection layers FL1 and FL2 may include at least one of urethane-acrylate or epoxy-acrylate. In addition, the second protection layer FL2 may further include at least one of silsesquioxane nano particles or silica nano particles.

In the second protection layer FL2, the silsesquioxane nano particles and the silica nano particles may be dispersed in a first polymer resin. The first polymer resin may include at least one of an epoxy-based resin, a urethane-based resin, an acrylic resin, or a silicon-based resin.

At a room temperature, the storage modulus of the first protection layer FL1 may be less than the Young's modulus of the second protection layer FL2. In an embodiment of the display device DD, the Young's modulus of the second protection layer FL2 disposed relatively outer side may be greater than the storage modulus of the first protection layer FL1. In the specification, the room temperature refers to a temperature in a range of about 20° C. to about 30° C., the storage modulus is measured using a Rheometer (Anton-Paar Company), and the Young's modulus is measured using a universal testing machine (UTM) (Instron Company).

The first protection layer FL1 may have a storage modulus in a range of about 0.005 megapascal (MPa) to about 0.2 MPa at a room temperature. A first protection layer having a storage modulus of less than about 0.005 MPa at a room temperature has degraded shape retention properties. A first protection layer having a storage modulus of greater than about 0.2 MPa at a room temperature does not absorb external impact and causes damage to a display device. In an embodiment, the first protection layer FL1 having a storage modulus in a range of about 0.005 MPa to about 0.2 MPa at a room temperature may exhibit high or improved impact resistance. A second thickness TH1 of the first protection layer FL1 may be in a range of about 100 micrometers (μm) to about 1 millimeter (mm). In an embodiment, for example, the second thickness TH1 of the first protection layer FL1 may be in a range of about 150 μm to about 1 mm. The second thickness TH1 of the first protection layer FL1 may be in a range of about 100 Vim or about 300 m. However, this is only an example, and the second thickness TH1 of the first protection layer FL1 is not limited thereto.

A first protection layer having a thickness of less than about 100 μm is vulnerable to external impact, and a first protection layer having a thickness of greater than about 1 mm increases the thickness of a display device. In an embodiment, the first protection layer FL1 having the thickness TH1 in a range of about 100 μm to about 1 mm may exhibit high impact resistance while maintaining the thickness of the display device DD at a desired level.

The second protection layer FL2 may have a Young's modulus in a range of about 1 gigapascal (GPa) to about 8 GPa at a room temperature. In an embodiment, for example, the Young's modulus of the second protection layer FL2 may be in a range of about 1 GPa to about 5 GPa, or about 1 GPa to about 4 GPa at a room temperature. A second protection layer having a Young's modulus of less than about 1 GPa at a room temperature is vulnerable to external impact, and a second protection layer having a Young's modulus of greater than about 8 GPa at a room temperature is peeled off from a display device during repeated folding and unfolding. In an embodiment, the second protection layer FL2 having a Young's modulus in a range of about 1 GPa to about 8 GPa may exhibit high folding reliability and high impact resistance.

In an embodiment, a first thickness TH2 of the second protection layer FL2 may be the same as the second thickness TH1 of the first protection layer FL1, or greater than the second thickness TH1 of the first protection layer FL1. In an embodiment of the display device DD, the second protection layer FL2 disposed relatively outer side may be formed to be thicker than the first protection layer FL1. In an embodiment, for example, the first thickness TH2 of the second protection layer FL2 may be about one time to about six times the second thickness TH1 of the first protection layer FL1. Alternatively, the first thickness TH2 of the second protection layer FL2 may be about one time to about five times the second thickness TH1 of the first protection layer FL1.

The first thickness TH2 of the second protection layer FL2 may be in a range of about 300 m to about 1 mm. A second protection layer having a thickness of less than about 300 μm is vulnerable to external impact, and a second protection layer having a thickness of greater than about 1 mm increases the thickness of a display device. In an embodiment, the second protection layer FL2 having the thickness TH2 in a range of about 300 μm to about 1 mm may exhibit high impact resistance while maintaining the thickness of the display device DD at a desired level.

The protection member PF may have a pencil hardness of about 3 H or greater measured according to ASTM D3363. The protection member PF having a pencil hardness of about 3 H or greater measured according to ASTM D3363 may exhibit high reliability.

A third thickness TH3 of the protection member PF may be in a range of about 400 m to about 2 mm. In an embodiment, for example, the third thickness TH3 of the protection member PF may be about 600 μm. A protection member having a thickness of less than about 400 μm is vulnerable to external impact, and a protection member having a thickness of greater than about 2 mm increases the thickness of a display device. In an embodiment, the protection member PF having the thickness TH3 in a range of about 400 μm to about 2 mm may exhibit high impact resistance while maintaining the thickness of the display device DD at a desired level.

FIG. 5 is a cross-sectional view showing another embodiment of the invention, and compared to the optical layer OPL illustrated in FIG. 4, an optical layer OPL-a of FIG. 5 differs in that the optical layer OPL-a includes a light control layer FCL instead of the first to third filters CF1, CF2, and CF3. In addition, FIG. 5 illustrates that a low-reflection layer LFA is further disposed between the display element layer DP-ED and the encapsulation layer TFE. Hereinafter, in describing FIG. 5, any repetitive detailed description of the same contents as those described with reference to FIG. 1 to FIG. 4 will be omitted, and instead, differences will be mainly described.

Referring to FIG. 5, the light control layer FCL may fill the pattern opening P_OH, and may be disposed on the pattern portion CPT. The light control layer FCL may a planarization layer. The light control layer FCL may be an anti-reflection layer which reduces the reflectance of external light incident from the outside. The light control layer FCL may be a layer which selectively transmits light emitted from the display panel DP. The light control layer FCL may include a pigment or a dye. The pigment or the dye included in the light control layer FCL may be a material which transmits only the light of a specific wavelength region among light emitted from the display element layer DP-ED. Accordingly, the optical layer OPL-a including the light control layer FCL may improve the display quality and light efficiency of the display device DD.

The low-reflection layer LFA may be disposed on the display element layer DP-ED. In an embodiment, for example, the low-reflection layer LFA may be disposed on the capping layer CPL, or the capping layer CPL may be omitted, and the low-reflection layer LFA may be disposed on the second electrode EL2. The low-reflection layer LFA may include an inorganic material having a low reflectance, and may include a metal or a metal oxide. In an embodiment, for example, the low-reflection layer LFA may include ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fe), nickel (Ni), tantalum (Ta), manganese (Mn), zinc (Zn), germanium (Ge), silver (Ag), magnesium (Mg), gold (Au), copper (Cu), calcium (Ca), or a combination thereof. Alternatively, the low-reflection layer LFA may include, for example, SiO₂, TiO₂, ZrO₂, Ta₂O₅, HfO₂, Al₂O₃, ZnO, Y₂O₃, BeO, MgO, PbO₂, WO₃, SiNx, LiF, CaF₂, MgF₂, CdS, or a combination thereof.

The low-reflection layer LFA may have an absorption coefficient (k) of about 1.5 or less. In an embodiment, for example, the low-reflection layer LFA may have an absorption coefficient of greater than about 0.5 and less than about 1.5. The low-reflection layer LFA having an absorption coefficient of greater than about 0.5 and less than about 1.5 may reduce reflectance of light.

The low-reflection layer LFA may induce destructive interference of light incident to the inside of the display device DD and light reflected from a metal (e.g., a second electrode) disposed in a lower portion of the low-reflection layer LFA to reduce external light reflectance. Accordingly, an embodiment of the display device DD including the low-reflection layer LFA may have improved display quality and light efficiency.

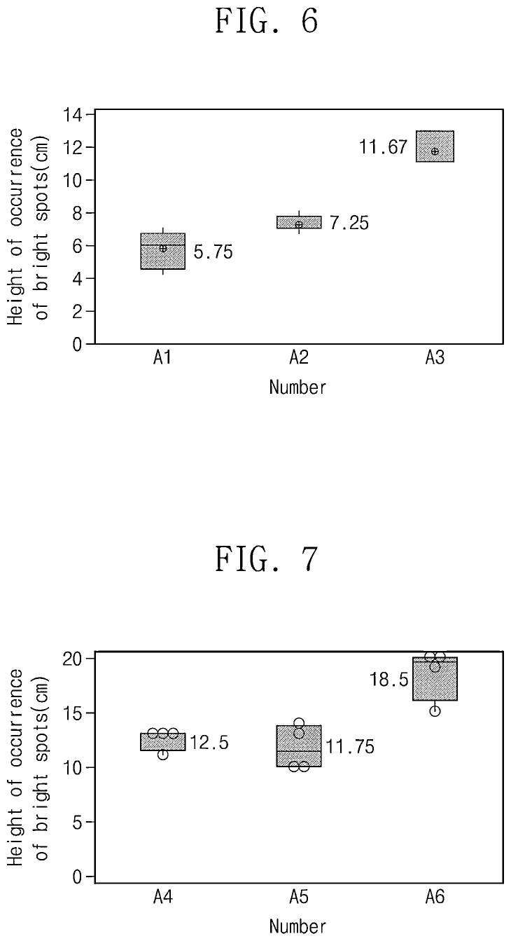

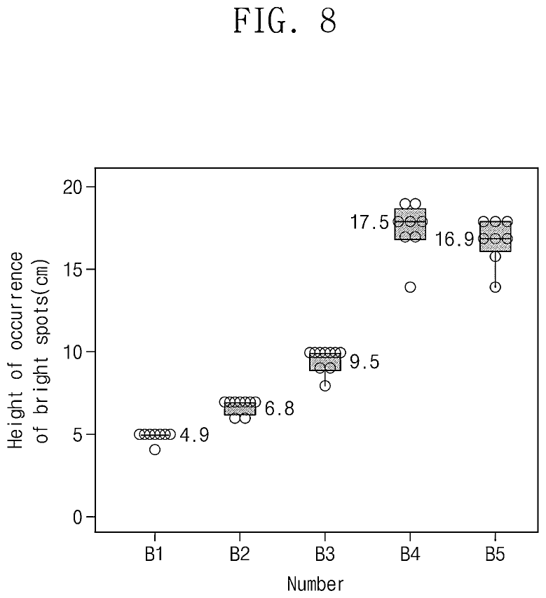

FIGS. 6 and 7 are graphs showing the measurement of the height of occurrence of bright spots in protection members of Comparative Examples and Experimental Examples of Table 1. In FIGS. 6 and 7, the height of occurrence of bright spots was evaluated using a Dupont tester (a product by Qmesys Company), and an impact jig having a diameter of 6.5 mm (φ6.5) was used. The height of occurrence of bright spots represents an average value of four evaluations.

In Table 1, Comparative Example A1 is A1 in FIG. 6, Experimental Example A2 is A2 in FIG. 6, and Experimental Example A3 is A3 in FIG. 6. Comparative Example A4 is A4 in FIG. 7, Experimental Example A5 is A5 in FIG. 7, and Experimental Example A6 is A6 in FIG. 7.

TABLE 1

| | | | | | | Glass |
|---|---|---|---|---|---|---|
| | | | | | | transition |
| | | | Thickness | Young's modulus or | | temperature |
| | | Material | (μm) | storage modulus | | (Tg, ° C.) |
| Comparative | Second | Epoxy-based resin | 100 | 1.1 | GPa | 34.8 |
| Examples A1 | protection | | | | | |
| | layer | | | | | |
| | First | First acrylic resin | 500 | 0.13 | MPa | −11 |
| | protection | | | | | |
| | layer | | | | | |
| Experimental | Second | Epoxy-based resin | 300 | 1.1 | GPa | 34.8 |
| Examples A2 | protection | | | | | |
| | layer | | | | | |
| | First | First acrylic resin | 300 | 0.13 | MPa | −11 |
| | protection | | | | | |
| | layer | | | | | |
| Experimental | Second | Epoxy-based resin | 500 | 1.1 | GPa | 34.8 |
| Examples A3 | protection | | | | | |
| | layer | | | | | |
| | First | First acrylic resin | 100 | 0.13 | MPa | −11 |
| | protection | | | | | |
| | layer | | | | | |
| Comparative | Second | Second acrylic resin | 100 | 2.2 | GPa | 48.6 |
| Examples A4 | protection | | | | | |
| | layer | | | | | |
| | First | First acrylic resin | 500 | 0.13 | MPa | −11 |
| | protection | | | | | |
| | layer | | | | | |
| Experimental | Second | Second acrylic resin | 300 | 2.2 | GPa | 48.6 |
| Examples A5 | protection | | | | | |
| | layer | | | | | |
| | First | First acrylic resin | 300 | 0.13 | MPa | −11 |
| | protection | | | | | |
| | layer | | | | | |
| Experimental | Second | Second acrylic resin | 500 | 2.2 | GPa | 48.6 |
| Examples A6 | protection | | | | | |
| | layer | | | | | |
| | First | First acrylic resin | 100 | 0.13 | MPa | −11 |
| | protection | | | | | |
| | layer | | | | | |

Referring to Table 1, in the protection member of each of Comparative Examples and Experimental Examples, the first protection layer includes a first acrylic resin, and the second protection layer includes an epoxy-based resin or a second acrylic resin. The first acrylic resin included in the first protection layer and the second acrylic resin included in the second protection layer include the same acrylic monomer, but are formed from a composition including different components (e.g., an oligomer, an additive, and the like). In the protection member of each of Comparative Examples and Experimental Examples of Table 1, the second protection layer was formed by adjusting components of the composition so as to have a relatively high Young's modulus.

In the “Young's modulus or storage modulus” of Table 1, the second protection layer shows the Young's modulus, and the first protection layer shows the storage modulus. In the protection member of each of Experimental Examples A2, A3, A5, and A6, the Young's modulus of the second protection layer is in a range of about 1.1 GPa or about 2.2 GPa, which satisfies the Young's modulus of the second protection layer according to an embodiment. In the protection member of each of Experimental Examples A2, A3, A5, and A6, the thickness of the second protection layer is in a range of about 300 μm or about 500 μm, which satisfies the thickness of the second protection layer according to an embodiment. In an embodiment, the second protection layer may have a Young's modulus in a range of about 1 GPa to about 8 GPa, and the second protection layer may have a thickness of about 300 μm to about 1 mm. In the protection member of each of Comparative Examples A1 and A4, the thickness of the second protection layer is about 100 μm, which is less than the minimum value (i.e., 300 μm) of the thickness of the second protection layer according to an embodiment.

Table 2 shows the pencil hardness evaluated for the protection members of Comparative Examples and Examples in Table 1 and the height of occurrence of bright spots in FIGS. 6 and 7. The pencil hardness was evaluated according to the standard specification of ASTM D3363. In Table 2, “Fail” means that the surface of the protection member was damaged during the pencil hardness evaluation. The impact resistance is determined to be great or high if the height of occurrence of bright spots is about 7 centimeters (cm) or greater.

TABLE 2

| | | Height of occurrence of |
|---|---|---|
| | Pencil hardness | bright spots (cm) |
| Comparative | Fail | 5.75 |
| Example A1 | | |
| Experimental | 3 H | 7.25 |
| Example A2 | | |
| Experimental | 3 H | 11.67 |
| Example A3 | | |
| Comparative | Fail | 12.5 |
| Example A4 | | |
| Experimental | 3 H | 11.75 |
| Example A5 | | |
| Experimental | 3 H | 18.5 |
| Example A6 | | |

Referring to FIGS. 6 and 7 and Table 2, it can be seen that the protection member of each of Experimental Examples A2, A3, A5, and A6 has a height of occurrence of bright spots of about 7 cm or greater, and thus has high impact resistance. Referring to Table 2, it can be seen that the protection members of Experimental Examples A2, A3, A5, and A6 have desired pencil hardness evaluation results of 3 H. In addition, the protection member of each of Experimental Examples A3 and A6 includes the second protection layer having a thickness of 500 μm, and has a height of occurrence of bright spots of about 11 cm or greater, so that it can be seen that the impact resistance thereof is high. As described above with reference to Table 1, the protection members of Experimental Examples A2, A3, A5, and A6 satisfy the thickness of the second protection layer and the Young's modulus of the second protection layer according to an embodiment. Accordingly, in an embodiment, a protection member including a second protection layer which has a thickness in a range of about 300 μm to about 1 mm, and has a Young's modulus in a range of about 1 GPa to about 8 GPa may exhibit high impact resistance.

In addition, it can be seen that surfaces of the protection members of Comparative Examples A1 and A4 were damaged during the pencil hardness evaluation. In addition, it can be seen that the protection member of Comparative Example A1 has a low height of occurrence of bright spots of about 5.75 cm. As described above with reference to Table 1, in the protection member of each of Comparative Examples A1 and A4, the thickness of the second protection layer is less than about 300 μm. Accordingly, the protection member of Comparative Example A1 has a low height of occurrence of bright spots, and the surfaces of the protection member of each of Comparative Examples A1 and A4 were damaged during the pencil hardness evaluation.

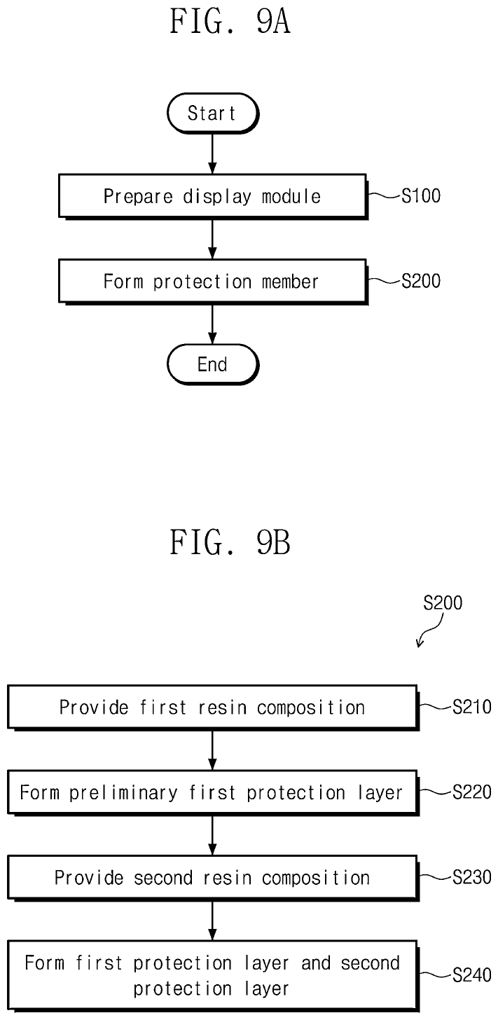

FIG. 8 and Table 4 show the measurement of the height of occurrence of bright spots in protection members of Comparative Examples and Experimental Examples of Table 3. FIG. 8 and Table 4 are the evaluations through a Dupont tester (a product of Qmesys Company), and the height of occurrence of bright spots was measured using a drop jig having a weight of 30 grams (g), and the average value of 8 evaluations is shown. In Table 3, Comparative Example B1 is B1 in FIG. 8, Comparative Example B2 is B2 in FIG. 8, and Experimental Example B3 is B3 in FIG. 8. Experimental Example B4 is B4 in FIG. 8, and Experimental Example B5 is B5 in FIG. 8.

TABLE 3

| | | | | Young's modulus | | Glass transition |
|---|---|---|---|---|---|---|
| | | | Thickness | or storage | | temperature |
| | | Material | (μm) | modulus | | (Tg, ° C.) |
| Comparative | Second | Epoxy-based resin | 100 | 1.1 | GPa | 34.8 |
| Examples B1 | protection | | | | | |
| | layer | | | | | |
| | First | Third acrylic resin | 500 | 0.46 | MPa | 13 |
| | protection | | | | | |
| | layer | | | | | |
| Comparative | Second | Epoxy-based resin | 300 | 1.1 | GPa | 34.8 |
| Examples B2 | protection | | | | | |
| | layer | | | | | |
| | First | Third acrylic resin | 300 | 0.46 | MPa | 13 |
| | protection | | | | | |
| | layer | | | | | |
| Experimental | Second | Epoxy-based resin | 500 | 1.1 | GPa | 34.8 |
| Examples B3 | protection | | | | | |
| | layer | | | | | |
| | First | Fourth acrylic resin | 100 | 0.026 | MPa | −42.7 |
| | protection | | | | | |
| | layer | | | | | |
| Experimental | Second | Epoxy-based resin | 300 | 1.1 | GPa | 34.8 |
| Examples B4 | protection | | | | | |
| | layer | | | | | |
| | First | Fourth acrylic resin | 300 | 0.026 | MPa | −42.7 |
| | protection | | | | | |
| | layer | | | | | |
| Experimental | Second | Epoxy-based resin | 300 | 1.1 | GPa | 34.8 |
| Examples B5 | protection | | | | | |
| | layer | | | | | |
| | First | Fifth acrylic resin | 300 | 0.022 | MPa | −39.6 |
| | protection | | | | | |
| | layer | | | | | |

Referring to Table 3, in the protection member of each of Comparative Examples and Experimental Examples, the first protection layer includes any one among third to fifth acrylic resins, and the second protection layer includes an epoxy-based resin. In the protection member of each of Comparative Examples and Experimental Examples, the third to fifth acrylic resins included in the first protection layer include the same acrylic monomer, but are formed from a composition including different components (e.g., an oligomer, an additive, and the like).

In the “Young's modulus or storage modulus” of Table 3, the second protection layer shows the Young's modulus, and the first protection layer shows the storage modulus. In the protection member of each of Experimental Examples B3 to B5, the Young's modulus of the second protection layer is about 1.1 GPa, which satisfies the Young's modulus of the second protection layer according to an embodiment. In the protection member of each of Experimental Examples B3 to B5, the thickness of the second protection layer is in a range of about 300 μm or about 500 μm, which satisfies the thickness of the second protection layer according to an embodiment. In an embodiment, the second protection layer may have a Young's modulus of about 1 GPa to about 8 GPa, and the second protection layer may have a thickness in a range of about 300 μm to about 1 mm. In the protection member of Comparative Example B1, the thickness of the second protection layer is about 100 m, which is less than the minimum value (i.e., 300 μm) of the thickness of the second protection layer according to an embodiment. In addition, in the protection member of each of Comparative Examples B1 and B2, the storage modulus of the first protection layer is about 0.46 MPa, which is greater than the maximum value (i.e., 0.2 MPa) of the storage modulus of the first protection layer according to an embodiment.

TABLE 4

| | Height of occurrence of |
|---|---|
| | bright spots (cm) |
| Comparative | 4.9 |
| Example B1 | |
| Comparative | 6.8 |
| Example B2 | |
| Experimental | 9.5 |
| Example B3 | |
| Experimental | 17.5 |
| Example B4 | |
| Experimental | 16.9 |
| Example B5 | |

Referring to FIG. 8 and Table 4, it can be seen that the protection member of each of Experimental Examples B3 to B5 has a height of occurrence of bright spots of about 7 cm or greater, and thus exhibits high impact resistance. As described above with reference to Table 3, the protection members of Experimental Examples B3 to B5 satisfy the thickness of the second protection layer and the storage modulus of the first protection layer according to an embodiment. Accordingly, in an embodiment, a protection member including a second protection layer which has a thickness in a range of about 300 μm to about 1 mm, and a first protection layer having a storage modulus in a range of about 0.005 MPa to about 2.0 MPa may exhibit high impact resistance.

The protection members of Comparative Examples B1 and B2 respectively have a height of occurrence of bright spots of about 4.9 cm and about 6.8 cm, and the height of occurrence of bright spots is as low as less than about 7 cm. As described above with reference to Table 3, in the protection member of each of Comparative Examples B1 and B2, the storage modulus of the first protection layer is greater than about 0.2 MPa, and thus exhibits a low height of occurrence of bright spots. In addition, in the protection member of Comparative Example B1, the thickness of the second protection member is about 100 μm, and thus exhibits a relatively further lower height of occurrence of bright spots.

The display device of an embodiment may include a protection member directly disposed on a display module. The protection member may include a first protection layer and a second protection layer disposed on the first protection layer. The first protection layer may have a storage modulus in a range of about 0.005 MPa to about 0.2 MPa, and the second protection layer may have a thickness in a range of about 300 m to about 1 mm, and may have a Young's modulus in a range of about 1 GPa to about 8 GPa at a room temperature. Accordingly, the display device including the protection member of an embodiment may exhibit high impact resistance.

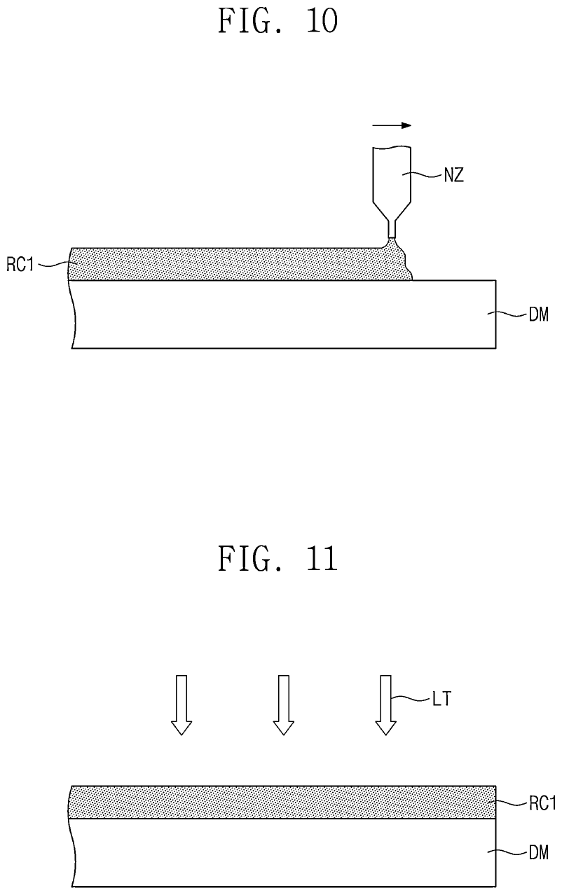

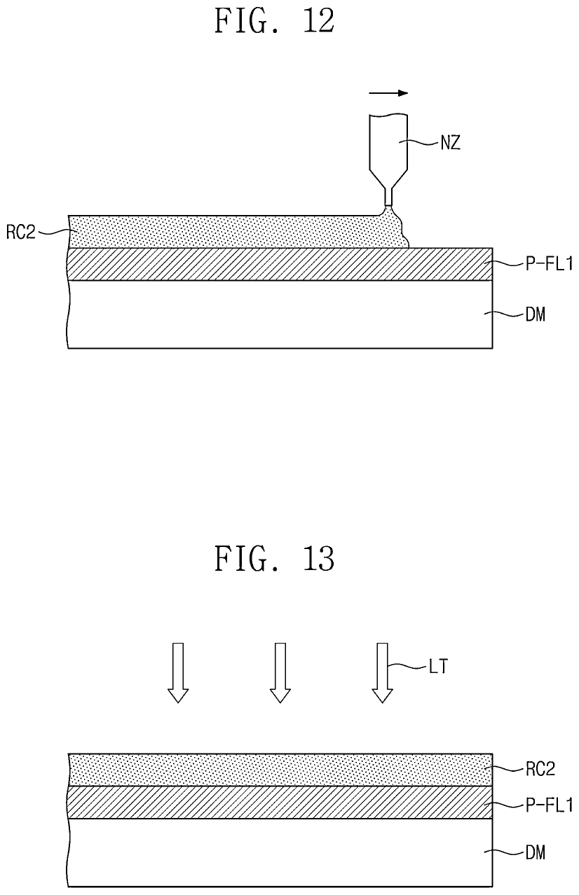

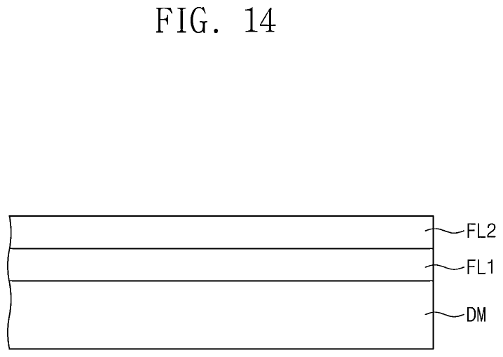

The display device of an embodiment may be formed by the method for manufacturing a display device of an embodiment. FIGS. 9A and 9B are flowcharts showing the method for manufacturing a display device of an embodiment of the invention. FIG. 10 to FIG. 14 are cross-sectional views schematically showing processes of the method for manufacturing a display device of an embodiment of the invention. Hereinafter, in describing the method for manufacturing a display device of an embodiment with reference to FIG. 9A to FIG. 14, any repetitive detailed description of the same contents as those described above with reference to FIG. 1 to FIG. 5 will be omitted. Instead, the description will mainly focus on differences.

Referring to FIG. 9A, the method for manufacturing a display device of an embodiment may include preparing a display module S100 and forming (or providing) a protection member on the display module S200. Referring to FIG. 9B, the forming of a protection member S200 may include providing a first resin composition S210, forming a preliminary first protection layer from the first resin composition S220, providing a second resin composition S230, and forming a first protection layer from the preliminary first protection layer and forming a second protection layer from the second resin composition.

In an embodiment, the forming of a protection member S200 may be performed at a temperature in a range of a room temperature to a temperature of about 80° C. The protection member PF may be directly disposed on the display module DM. If a protection member is formed at a temperature of higher than 80° C., components such as a light emitting layer included in the display module are damaged. If a protection member is formed at a temperature lower than the room temperature (e.g., at a temperature lower than about 20° C.), first and second resin compositions for forming the protection member may not be easily provided. Accordingly, the method for manufacturing a display device of an embodiment including the forming of a protection member on the display module DM at a temperature in a range of a room temperature to a temperature of about 80° C. may exhibit high manufacturing efficiency and manufacturing reliability.

FIG. 10 shows a process of providing a first resin composition RC1 on the display module DM. The first resin composition RC1 may be directly provided on the display module DM. A conventional method for manufacturing a display device including forming a first protection layer by providing a resin composition to a separate temporary member has an additional manufacturing step, so that manufacturing cost and manufacturing time are increased. In an embodiment, the method for manufacturing a display device of an embodiment including directly providing the first resin composition RC1 on the display module DM may exhibit high manufacturing efficiency.

The first resin composition RC1 may be provided by an inkjet printing method, a dispensing method, or a slot-die coating method. In FIG. 10, the first resin composition RC1 is illustrated as being provided through a nozzle NZ. However, this is only an example, and a device which provides the first resin composition RC1 is not limited thereto.

The first resin composition RC1 may include at least one of an epoxy-based resin, a urethane-based resin, an acrylic resin, or a silicon-based resin. In addition, the first resin composition RC1 may further include a materials for improving impact resistance within a range that does not degrade the display quality and process reliability of the display device DD.

The first resin composition RC1 may include a solvent in an amount in a range of about 0 weight precent (wt %) to about 10 wt % based on the total weight of the first resin composition RC1. That is, the first resin composition RC1 may not include a solvent, or may include a solvent in an amount of about 10 wt % or less based on the total weight thereof. A resin composition including greater than 10 wt % of a solvent has degraded shape retention properties due to the occurrence of a “flow,” or is not applied to a uniform thickness and/or in a uniform amount, so that a protection layer is not easily formed. The “flow” refers to a phenomenon in which a composition flows out of a desired member. In an embodiment, the first resin composition RC1 including a solvent in an amount in a range of about 0 wt % to about 10 wt % based on the total weight thereof may be applied to a uniform thickness and in a uniform amount, and may exhibit high shape retention properties.

FIG. 11 shows a process of curing the first resin composition RC1 directly provided on the display module DM. In the curing of the first resin composition RC1, heat (not shown) or light LT may be provided to the first resin composition RC1. In FIG. 11, curing the first resin composition RC1 by providing the light LT to the first resin composition RC1 is illustrated as an example. The preliminary first protection layer P-FL1 illustrated in FIG. 12 may be formed by the curing of the first resin composition RC1. The preliminary first protection layer P-FL1 may have a curing rate of about 50% or less. In an embodiment, for example, the curing rate may be measured by a gel fraction method. However, the embodiment of the invention is not limited thereto, and any curing rate measurement method known in the art can be applied to the invention.

Referring to FIG. 12, on the preliminary first protection layer P-FL1, a second resin composition RC2 may be provided. The second resin composition RC2 may be directly disposed on the preliminary first protection layer P-FL1. The method for manufacturing a display device of an embodiment including directly providing the second resin composition RC2 on the preliminary first protection layer P-FL1 may exhibit high manufacturing efficiency.

The second resin composition RC2 may be provided by an inkjet printing method, a dispensing method, or a slot-die coating method. In FIG. 12, the second resin composition RC2 is illustrated as being provided through the nozzle NZ. However, this is only an example, and a device which provides the second resin composition RC2 is not limited thereto.

The second resin composition RC2 may include at least one of an epoxy-based resin, a urethane-based resin, an acrylic resin, or a silicon-based resin. The second resin composition RC2 may further include at least one of silsesquioxane nano particles or silica nano particles. In addition, the second resin composition RC2 may further include a materials for improving impact resistance within a range that does not degrade the display quality and process reliability of the display device DD.

The second resin composition RC2 may include a solvent in an amount in a range of about 0 wt % to about 10 wt % based on the total weight of the second resin composition RC2. That is, the second resin composition RC2 may not include a solvent, or may include a solvent in an amount of about 10 wt % or less based on the total weight thereof. A resin composition including greater than 10 wt % of a solvent has degraded shape retention properties due to the occurrence of a “flow,” or is not applied to a uniform thickness and/or in a uniform amount, so that a protection layer is not easily formed. In an embodiment, the second resin composition RC2 including a solvent in an amount in a range of about 0 wt % to about 10 wt % based on the total weight thereof may be applied to a uniform thickness and in a uniform amount, and may exhibit excellent shape retention properties.

FIGS. 13 and 14 illustrate a process of curing the preliminary first protection layer P-FL1 and the second resin composition RC2 to form the first protection layer FL1 and the second protection layer FL2. In an embodiment, the heat or the light LT may be provided to the preliminary first protection layer P-FL1 and the second resin composition RC2 to cure the preliminary first protection layer P-FL1 and the second resin composition RC2. In FIG. 13, curing the preliminary first protection layer P-FL1 and the second resin composition RC2 by providing the light LT to the preliminary first protection layer P-FL1 and the second resin composition RC2 is illustrated as an example. The first protection layer FL1 may be formed from the preliminary first protection layer P-FL1, and the second protection layer FL2 may be formed from the second resin composition RC2. The preliminary first protection layer P-FL1 and the second resin composition RC2 may be cured simultaneously during a same process.

In an embodiment, the second protection layer FL2 may have a Young's modulus in a range of about 1 GPa to about 8 GPa and the thickness TH2 (see FIG. 4) in a range of about 300 μm to about 1 mm at a room temperature. The first protection layer FL1 may have a storage modulus in a range of about 0.005 MPa to about 0.2 Mpa and the thickness TH1 (see FIG. 4) in a range of about 100 μm to about 1 mm at the room temperature.

The display device of an embodiment may be provided by the method for manufacturing a display device of an embodiment. The method for manufacturing a display device of an embodiment may include preparing a display module and forming a protection member on the display module. The forming of a protection member may be performed at a temperature in a range of a room temperature to about 80° C. Accordingly, the protection member may be directly formed on the display module, and the method for manufacturing a display device of an embodiment may exhibit high manufacturing efficiency.

A display device of an embodiment includes a protection member with an optimized modulus and/or thickness, and thus, may exhibit high impact resistance.

A method for manufacturing a display device of an embodiment may exhibit high manufacturing efficiency by optimizing the temperature of a process of forming a protection member.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display module; and
a protection member disposed on the display module, wherein the protection member includes:
a first protection layer having a storage modulus in a range of about 0.005 MPa to about 0.2 MPa at a room temperature; and
a second protection layer disposed on the first protection layer, having a first thickness in a range of about 300 μm to about 1 mm, and having a Young's modulus in a range of about 1 GPa to about 8 GPa at the room temperature.

2. The display device of claim 1, wherein the protection member is directly disposed on the display module.

3. The display device of claim 1, wherein the protection member does not include a glass substrate.

4. The display device of claim 1, wherein the first protection layer has a second thickness in a range of about 100 μm to about 1 mm.

5. The display device of claim 1, wherein the first thickness of the second protection layer is greater than or equal to a second thickness of the first protection layer.

6. The display device of claim 1, wherein the protection member has a third thickness in a range of about 400 μm to about 2 mm.

7. The display device of claim 1, wherein the second protection layer is directly disposed on the first protection layer.

8. The display device of claim 1, wherein each of the first protection layer and the second protection layer includes at least one of an epoxy-based resin, a urethane-based resin, an acrylic resin, or a silicon-based resin.

9. The display device of claim 8, wherein the second protection layer further comprises at least one of silsesquioxane nano particles or silica nano particles.

10. The display device of claim 1, wherein no polarizing plate is included.

11. The display device of claim 1, wherein the display module comprises a display panel and an optical layer disposed on the display panel,
wherein the optical layer includes a pigment or a dye.

12. The display device of claim 11, wherein the optical layer includes:
a pattern portion in which a pattern opening is defined; and
first to third filters each of which includes the pigment or the dye, and is disposed while filling the pattern opening.

13. The display device of claim 12, wherein the optical layer further comprises an overcoat layer disposed on the first to third filters.

14. The display device of claim 11, wherein the optical layer includes:
a pattern portion in which a pattern opening is defined; and
a light control layer including the pigment or the dye, and disposed on the pattern portion while filling the pattern opening.

15. A method for manufacturing a display device, the method comprising:
preparing a display module including a display panel and an optical layer disposed on the display panel, wherein the optical layer includes a pigment or a dye; and
forming a protection member on the display module at a temperature in a range of a room temperature to about 80° C.,
wherein the forming the protection member includes:
providing a first resin composition on the display module;
forming a preliminary first protection layer by curing the first resin composition;
providing a second resin composition on the preliminary first protection layer; and
forming a first protection layer and a second protection layer of the protection member by curing the preliminary first protection layer and the second resin composition.

16. The method of claim 15, wherein the first resin composition is directly provided on the display module.

17. The method of claim 15, wherein the second resin composition is directly provided on the preliminary first protection layer.

18. The method of claim 15, wherein the preliminary first protection layer and the second resin composition are cured during a same process.

19. The method of claim 15, wherein each of the first resin composition and the second resin composition is provided by an inkjet printing method, a dispensing method, or a slot-die coating method.

20. The method of claim 15, wherein the first resin composition comprises a solvent in an amount in a range of about 0 wt % to about 10 wt % based on a total weight of the first resin composition.

21. The method of claim 15, wherein the second resin composition comprises a solvent in an amount in a range of about 0 wt % to about 10 wt % based on a total weight of the second resin composition.

22. The method of claim 15, wherein each of the first resin composition and the second resin composition includes at least one of an epoxy-based resin, a urethane-based resin, an acrylic resin, or a silicon-based resin.

23. The method of claim 22, wherein the second resin composition further comprises at least one of silsesquioxane nano particles or silica nano particles.

24. The method of claim 15, wherein the second protection layer has a Young's modulus in a range of about 1 GPa to about 8 GPa at the room temperature, and the second protection layer has a first thickness in a range of about 300 μm to about 1 mm.

25. The method of claim 15, wherein the first protection layer has a storage modulus in a range of about 0.005 MPa to about 0.2 MPa at the room temperature, and the first protection layer has a second thickness in a range of about 100 μm to about 1 mm.
